(19) United States
(12) Patent Application Publication
(10) Pub. No.: US 2024/0339364 A1
(43) Pub. Date: Oct. 10, 2024

(54) APPARATUS AND METHOD FOR FABRICATING DISPLAY PANEL

(71) Applicant: Samsung Display Co., LTD., Yongin-si (KR)

(72) Inventors: Hee Jung LEE, Yongin-si (KR); Hong Gi MIN, Yongin-si (KR); Jong Sung KIM, Yongin-si (KR); Sang Jin LEE, Yongin-si (KR); Myung Soo HUH, Yongin-si (KR)

(73) Assignee: Samsung Display Co., LTD., Yongin-si (KR)

(21) Appl. No.: 18/517,343

(22) Filed: Nov. 22, 2023

(30) Foreign Application Priority Data
Apr. 7, 2023 (KR) 10-2023-0045874

(51) Int. Cl. H01L 21/66; H01L 33/00

(52) U.S. Cl. CPC H01L 22/20; H01L 33/005

(57) ABSTRACT

An apparatus for fabricating a display panel includes a loading plate on which a fabrication substrate is loaded, a plurality of optical microscopes that captures the fabrication substrate and alignment marks of the fabrication substrate, a gripper driver that aligns the fabrication substrate by adjusting a gap between gripper units and rotating the gripper units; and a substrate alignment controller that calculates an amount of rotation correction for the gripper units based on a deviated angle of the fabrication substrate to supply it to the gripper driver, calculates a gripper gap setting value for adjusting the gap between the gripper units using a residual of the aligned fabrication substrate, and provides the gripper gap setting value to the gripper driver.

This application claims priority to and benefits of Korean Patent Application No. 10-2023-0045874 under 35 U.S.C. 119, filed on Apr. 7, 2023, in the Korean Intellectual Property Office (KIPO), the entire contents of which are incorporated herein by reference.

### BACKGROUND

### 1. Technical Field

The disclosure relates to an apparatus and a method for fabricating a display panel.

### 2. Description of the Related Art

Display devices become more and more important as multimedia technology evolves. Accordingly, a variety of types of display devices such as organic light-emitting display (OLED) devices and liquid-crystal display (LCD) devices are currently used.

Display devices include a display panel such as a light-emitting display panel and a liquid-crystal display panel for displaying images. Among them, light-emitting display panel may include light-emitting diodes (LEDs). Light-emitting diodes may include an organic light-emitting diode using an organic material as a luminescent material, an inorganic light-emitting diode using an inorganic material as a luminescent material, etc.

In order to fabricate a light-emitting diode display panel using inorganic or organic light-emitting diodes as light-emitting diodes, a process of placing a transparent insulating substrate such as silicon and glass on a fabrication device such as a deposition device, a printing device and a bonding device is required. In doing so, a transparent insulating substrate is precisely placed on a loading plate of a fabrication device using an alignment device.

### SUMMARY

The disclosure provides an apparatus for fabricating a display panel that can quickly and accurately align a transparent insulating substrate (hereinafter referred to as a fabrication substrate) for fabricating display panels with fabricating devices such as an inkjet printing device.

The disclosure provides an apparatus for fabricating a display panel that can correct the alignment position or angle of a fabrication substrate by precisely adjusting the gap between alignment axes based on a residual.

It should be noted that objects of the disclosure are not limited to the above-mentioned object; and other objects of the disclosure will be apparent to those skilled in the art from the following descriptions.

According to an embodiment of the disclosure, an apparatus for fabricating a display panel may include a loading plate on which a fabrication substrate is loaded, a plurality of optical microscopes that captures the fabrication substrate and a plurality of alignment marks of the fabrication substrate, a gripper driver that aligns the fabrication substrate by adjusting gap between gripper units and rotating the gripper units; and a substrate alignment controller that calculates an amount of rotation correction for the gripper units based on a deviated angle of the fabrication substrate to supply the amount of rotation correction for the gripper units to the gripper driver, calculates a gripper gap setting value for adjusting the gap between the gripper units using a residual of the aligned fabrication substrate, and provides the gripper gap setting value to the gripper driver.

In an embodiment, the gripper driver may adjust the gap between the gripper units disposed on a side in a direction of the fabrication substrate in real time based on the gripper gap setting value input from the substrate alignment controller, and align and correct a deviation angle of the fabrication substrate by rotationally driving the gripper units around a central axis between the gripper units.

In an embodiment, the substrate alignment controller may receive captured image data of the fabrication substrate loaded on the loading plate from the plurality of optical microscopes, extract the plurality of alignment marks included in the captured image data, detect coordinates of the plurality of alignment marks on an axis and the deviation angle of the plurality of alignment marks relative to a reference line, and calculate a substrate rotation amount for correcting the deviation angle of the fabrication substrate using the deviation angle of the plurality of alignment marks relative to the reference line.

In an embodiment, the substrate alignment controller may convert the substrate rotation amount calculated based on the gap between the plurality of alignment marks into an amount of rotation correction for the gripper units based on the gap between the gripper units, and supply the amount of rotation correction to the gripper driver to rotate the gripper units according to the amount of rotation correction.

In an embodiment, the substrate alignment controller may additionally receive the captured image data of the optical microscopes on the loading plate from the optical microscopes, analyze the captured image data to detect the coordinates of the plurality of alignment marks on the axis and the deviation angle of the plurality of alignment marks relative to the reference line, and calculate the residual of the fabrication substrate and the plurality of alignment marks using the coordinates of the plurality of alignment marks on the axis and the deviation angle of the plurality of alignment marks relative to the reference line.

In an embodiment, the substrate alignment controller may calculate a total amount of rotation correction for final correction of the fabrication substrate using the substrate rotation amount, the amount of rotation correction for the gripper units, and the residual, and calculate an offset value for correcting distance between the gripper units by inversely calculating the total amount of rotation correction to compare the total amount of rotation correction with the gap between the gripper units.

In an embodiment, the substrate alignment controller may calculate a gripper gap setting value for adjusting the gap between the gripper units by adding or subtracting the offset value to or from the gap between the gripper units, and provide the gripper gap setting value to the gripper driver to correct and adjust the gap between the gripper units in real time.

In an embodiment, the substrate alignment controller may extract x-axis coordinates of a first alignment mark and a second alignment mark arranged in a y-axis direction among the plurality of alignment marks, and detects a first deviation angle of the first and second alignment marks relative to the reference line using a difference between the x-axis coordinates of the first and second alignment marks and Equation 1:

$$First Angle Δ X = AM ( 1 ) . X - AM ( 2 ) . X . \qquad [ Equation 1 ]$$

ΔX may be the first deviation angle of the first and second alignment marks, AM(1).X may be the x-axis coordinate of the first alignment mark, and AM(2).X may be the x-axis coordinate of the second alignment mark.

In an embodiment, the substrate alignment controller may calculate the x-axis coordinates of the first and second alignment marks and the first deviation angle of the plurality of alignment marks relative to the reference line using Equation 2 to calculate a substrate rotation amount for correcting the deviation angle of the fabrication substrate, calculate the substrate rotation amount calculated based on a gap between the first and second alignment marks using Equation 3, and convert the substrate rotation amount into an amount of rotation correction for a first gripper unit and a second gripper unit based on the gap between the first and second gripper units among the gripper units:

$$Substrate Rotation Amount ( θ ) = A TAN ( Δ X / MLL ) \times 18 \; 0 / π \qquad [ Equation 2 ]$$

$$[ Equation 3 ]$$

$$Amount of Rotation Correction RCV = TAN ( ( θ \times 180 / π ) \times GLL$$

Amount (θ) may be the substrate rotation amount, MLL may be the gap between the first and second alignment marks, RCV may be the amount of rotation correction, and GLL may be the gap between the first and second grippers.

In an embodiment, the substrate alignment controller may provide the amount of rotation correction to the gripper driver so that the first and second grippers are rotated based on the amount of rotation correction, and further receive the captured image data of the fabrication substrate after the fabrication substrate has been corrected by being rotated by the first and second grippers, and detects a second deviation angle of the first and second alignment marks using Equation 4:

$$Second Angle Δ {X}^{′} = AM ( 1 ) . X - AM ( 2 ) . X \qquad [ Equation 4 ]$$

ΔX′ may be the second deviation angle of the first and second alignment marks.

In an embodiment, the substrate alignment controller may calculate the second deviation angle of the first and second alignment marks, the gap between the first and second alignment marks, and the gap between the first and second grippers using Equation 5 to calculate the residual for additionally correcting the deviation angle of the fabrication substrate, and add or subtract the residual to or from the amount of rotation correction for the first and second grippers based on the gap between the first and second grippers using Equation 6 to calculate a total amount of rotation correction for final correction of the fabrication substrate:

$$Residual Δ CV = Δ {X}^{′} \times GLL / MLL \qquad [ Equation 5 ]$$

$$Total Amount of Rotation Correction Δ {CV}^{′} = RCV + Δ CV \qquad [ Equation 6 ]$$

ΔCV′ may be the total amount of rotation correction.

In an embodiment, the substrate alignment controller may inversely calculate the total amount of rotation correction using Equation 7 to compare the total amount of rotation correction with the gap between the first and second grippers, to calculate an offset value for correcting the gap between first and second grippers, and add or subtract the offset value to or from the gap between the first and second grippers using Equation 8 to calculate a gripper gap setting value for adjusting the gap between the first and second grippers:

$$Offset Value F\_Offset = Δ {CV}^{′} / ( TAN ( θ \times 180 / π ) - GLL ) \qquad [ Equation 7 ]$$

$$Gripper Gap Setting Value GGSet = GLL + F\_Offset \qquad [ Equation 8 ]$$

F_Offset may be the offset value for correcting the gap between first and second grippers, and GGSet may be the gripper gap setting value.

In an embodiment, the apparatus may further include a microscope mount module that mounts the plurality of optical microscopes and fixed and assembled to a main frame, and a frame transfer member that moves the main frame, the microscope mount module, the gripper driver and the substrate alignment controller toward the fabrication substrate along rails.

According to an embodiment of the disclosure, a method for fabricating a display panel may include loading a fabrication substrate onto a loading plate, capturing the fabrication substrate and alignment marks of the fabrication substrate with a plurality of optical microscopes, aligning the fabrication substrate by adjusting a gap between gripper units by a gripper driver and rotating the gripper units, and calculating an amount of rotation correction for the gripper units based on a deviation angle of the fabrication substrate to supply the deviation angle of the fabrication substrate to the gripper driver, calculating a gripper gap setting value for adjusting the gap between the gripper units using a residual of the aligned fabrication substrate, and providing the gripper gap setting value to the gripper driver.

In an embodiment, the aligning of the fabrication substrate by rotating the gripper units may include adjusting the gap between the gripper units disposed on a side in a direction of the fabrication substrate in real time based on the gripper gap setting value input from a substrate alignment controller, and aligning and correcting the deviation angle of the fabrication substrate by rotationally driving the gripper units around a central axis between the gripper units.

According to embodiments of the disclosure, it is possible to more quickly and accurately correct the alignment position or angle of fabrication substrates loaded on fabrication devices such as an inkjet printing device.

In addition, it is possible to save the time and cost for fabricating display panels by precisely adjusting the gap between the alignment axes of the grippers for correcting the alignment position or angle of the fabrication substrates based on a residual and correcting the alignment of the fabrication substrates to thereby reduce the number of alignment correction.

It should be noted that effects of the disclosure are not limited to those described above and other effects of the disclosure will be apparent to those skilled in the art from the following descriptions.

### BRIEF DESCRIPTION OF THE DRAWINGS

The above and other aspects and features of the disclosure will become more apparent by describing in detail embodiments thereof with reference to the attached drawings, in which:

FIG. 1 is a view showing a side of an apparatus for fabricating a display panel according to an embodiment of the disclosure.

FIG. 2 is a top view showing the alignment device and the fabrication substrate on the loading plate shown in FIG. 1.

FIG. 3 is a top view showing a process of checking if the fabrication substrate is properly aligned by the alignment device shown in FIG. 2.

FIG. 4 is a flowchart illustrating a method of aligning a fabrication substrate and correcting the alignment state of the fabricating substrate by the alignment device according to the embodiment of the disclosure.

FIG. 5 is a top view showing a process of checking if the fabrication substrate is properly aligned by the substrate alignment device and a process of disposing grippers shown in FIG. 2.

FIG. 6 is an enlarged view of area AA of FIG. 5 for illustrating a method of calculating the rotation amount of a fabrication substrate.

FIG. 7 is a view showing a method of calculating the rotation amount of grippers by converting the rotation amount of a fabrication substrate into the distance reference between alignment axes of the grippers.

FIG. 8 is a view illustrating a method of measuring a residual of a fabrication substrate.

FIG. 9 is a view showing a method of adjusting and correcting the gap between alignment axes of grippers using measured residual.

FIG. 10 is a graph showing results of comparing the amount of alignment correction of a fabrication substrate when the gap between alignment axes of grippers is adjusted, with the amount of alignment correction of a fabrication substrate according to the prior art.

### DETAILED DESCRIPTION OF THE EMBODIMENTS

The disclosure will now be described more fully hereinafter with reference to the accompanying drawings, in which embodiments of the disclosure are shown. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. The same reference numbers indicate the same components throughout the specification.

For the purposes of this disclosure, “at least one of A and B” may be construed as A only, B only, or any combination of A and B. Also, “at least one of X, Y, and Z” and “at least one selected from the group consisting of X, Y, and Z” may be construed as X only, Y only, Z only, or any combination of two or more of X, Y, and Z. As used herein, the term “and/or” includes any and all combinations of one or more of the associated listed items.

It will be understood that, although the terms “first,” “second,” etc. may be used herein to describe various elements, these elements should not be limited by these terms. These terms are only used to distinguish one element from another element. For instance, a first element discussed below could be termed a second element without departing from the teachings of the disclosure. Similarly, the second element could also be termed the first element.

Each of the features of the various embodiments of the disclosure may be combined or combined with each other, in part or in whole, and technically various interlocking and driving are possible. Each embodiment may be implemented independently of each other or may be implemented together in an association.

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

Hereinafter, embodiments of the disclosure will be described with reference to the accompanying drawings.

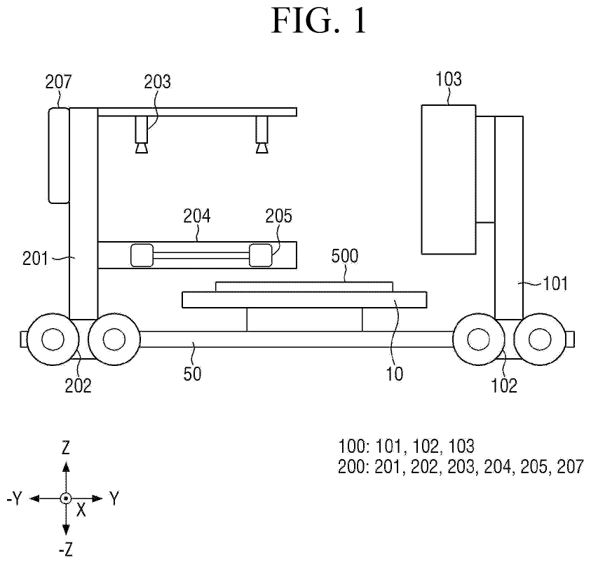

FIG. 1 is a view showing a side of an apparatus for fabricating a display panel according to an embodiment of the disclosure.

Referring to FIG. 1, the apparatus for fabricating a display panel may include at least one loading plate 10, rails 50, at least one fabrication process device 100, and at least one alignment device 200. The apparatus may further include a chamber in which the loading plate 10, the rails 50, the fabrication process device 100 and the alignment device 200 are disposed.

The chamber may provide an internal processing space where fabrication processes are carried out, such as inkjet printing, dispensing, coating, dipping, aligning, laminating, bonding, laser irradiating, and moving. The chamber may provide the processing space which is vacuum, can be heated up and cooled down, is soundproof, is vibration-free, and is waterproof. To this end, the chamber may further include a vacuum device, an air suction device, a purification device, a heating device, a cooling device, etc.

The loading plate 10 may be a plate on which a fabrication substrate 500 for fabricating a display panel is seated, and may be formed in a disk shape, or a rectangular or square plate shape.

On the loading plate 10, the fabrication substrate 500 for fabricating a display panel, for example, a wafer or a transparent glass substrate, may be mounted. The fabrication substrate 500 may include a pixel circuit substrate for forming multiple pixel electrodes, a light-emitting diode substrate, or the like.

The rails 50 may form a movement path of at least one loading plate 10, at least one fabrication process device 100, at least one alignment device 200, etc. The rails 50 may be in the form of a conveyor belt system or a transfer robot rather than simple rails.

The fabrication process device 100 may include a fabrication process device that performs at least one of inkjet printing, dispensing, coating, dipping, bonding, and laser irradiation. For example, the fabrication process device 100 may include a printing device that performs an inkjet printing process.

For example, the fabrication process device 100 performing an inkjet printing process may include an inkjet printer 103, a printer fixing frame 101, and a printer transfer member 102.

In case that the fabrication substrate 500 is loaded and aligned on the loading plate 10, the printer transfer member 102 may move the inkjet printer 103 mounted on the printer fixing frame 101 toward the fabrication substrate 500 together with the printer fixing frame 101.

The inkjet printer 103 may check if the fabrication substrate 500 is properly aligned on the loading plate 10 and perform an inkjet printing process on the fabrication substrate 500.

The alignment device 200 may include a microscope mount module in which multiple optical microscopes 203 is mounted, a gripper driver 204, a substrate alignment controller 207, a main frame 201, and a frame transfer member 202.

The optical microscopes 203 may be fixed and assembled to the main frame 201 through at least one microscope mount module. The optical microscopes 203 may be fixedly disposed at positions by at least one microscope mount module. The optical microscopes 203 may be previously fixed at the positions in line with alignment marks of the fabrication substrate 500 seated on the loading plate 10. For example, the optical microscopes 203 may be moved and disposed at the positions in line with the alignment marks of the fabrication substrate 500 in the z-axis direction.

The optical microscopes 203 may be moved in the y-axis direction, which is the length direction of the fabrication substrate 500, together with the main frame 201 and at least one microscope mount module by the transportation of the frame transfer member 202, and may be disposed at the positions in line with the alignment marks of the fabrication substrate 500 in the z-axis direction, which is the thickness direction of the fabrication substrate 500.

The optical microscopes 203 may capture the fabrication substrate 500 seated on the loading plate 10 based on a capture control signal from the substrate alignment controller 207, and transfer the captured image data to the substrate alignment controller 207.

The gripper driver 204 may adjust the gap between gripper units 205 disposed on the side in a direction (e.g., the x axis direction or the −x axis direction) of the fabrication substrate 500. The gripper units 205 may be rotationally driven with respect to the central axis between the gripper units 205 to align and correct a deviation angle of the fabrication substrate 500.

The gripper units 205 may press one side (e.g., the side in the x-axis direction or the −x-axis direction) of the fabrication substrate 500 seated on the loading plate 10 to correct the position or angle of the fabrication substrate 500. To this end, the gripper units 205 may be disposed on the side in a direction (e.g., the x-axis direction and the −x-axis direction) of the gripper driver 204. The gripper units 205 may be rotated with respect to the central axis between the gripper units 205 under the control of the gripper driver 204.

The gripper units 205 may rotate in the same direction as the plane direction of the fabrication substrate 500 by pushing, pulling or rotating the side of the fabrication substrate 500 so that the position or angle of the fabrication substrate 500 is corrected. For example, the gripper units 205 may be rotated clockwise or counterclockwise in parallel to the ground with respect to the center axis between the gripper units 205 so that the fabrication substrate 500 may be rotated clockwise or counterclockwise in parallel with the ground with respect to the central axis between the gripper units 205.

The gripper driver 204 may rotate the gripper units 205 clockwise or counterclockwise with respect to the central axis between the gripper units 205 in proportional to the amount of rotation correction set and input from the substrate alignment controller 207 in real time. The gripper driver 204 may correct and adjust the gap between the gripper units 205 according to the gripper gap setting value set and input from the substrate alignment controller 207 in real time.

The gripper driver 204 may rotate the gripper units 205 clockwise or counterclockwise with respect to the central axis between the gripper units 205 in proportional to the amount of rotation correction set and input from the substrate alignment controller 207 even after the gap between the gripper units 205 has been adjusted.

Once the optical microscopes 203 are disposed on the fabrication substrate 500 on the loading plate 10 and the gripper driver 204 and the gripper units 205 are disposed on a side of the fabrication substrate 500, the substrate alignment controller 207 may proceed with an alignment process of the fabrication substrate 500.

During the alignment process of the fabrication substrate 500, the substrate alignment controller 207 may transmit a capture control signal to each of the optical microscopes 203. The substrate alignment controller 207 may receive captured image data of the fabrication substrate 500 seated on the loading plate 10 from the optical microscopes 203.

The substrate alignment controller 207 may analyze the captured image data of the fabrication substrate 500 and extract multiple alignment marks included in the captured images. The substrate alignment controller 207 may detect the coordinates of the extracted alignment marks on an axis and a deviation angle of the alignment marks relative to a reference line.

The substrate alignment controller 207 may calculate the substrate rotation amount for correcting the deviation angle of the fabrication substrate 500 by using the coordinates of the alignment marks on the axis and the deviation angle of the alignment marks relative to the reference line. The substrate rotation amount may be numerical information on the rotation angle and rotation amount used for correcting a deviation angle of the fabrication substrate 500 based on the gap between the alignment marks.

The substrate alignment controller 207 may convert the rotation amount of the substrate calculated based on the gap between the alignment marks into the amount of rotation correction for the gripper units 205 based on the gap between the gripper units 205. The substrate alignment controller 207 may provide the converted amount of rotation correction to the gripper driver 204, and rotate the gripper units 205 according to the amount of the rotation correction by the gripper driver 204. For example, the gripper units 205 may be rotated clockwise or counterclockwise with respect to the central axis between the gripper units 205 by the gripper driver 204, and the fabrication substrate 500 may be also rotated clockwise or counterclockwise.

The substrate alignment controller 207 may transmit a capture control signal to each of the optical microscopes 203 and receive the captured image data of the fabrication substrate 500 seated on the loading plate 10 from the optical microscopes 203. The substrate alignment controller 207 may analyze the captured image data of the fabrication substrate 500 to again detect the coordinates of the extracted alignment marks on the axis and a deviation angle of the alignment marks relative to a reference line.

The substrate alignment controller 207 may detect the re-detected coordinates of the alignment marks on the axis and the deviation angle of the alignment marks relative to the reference line to detect a residual of the alignment marks of the fabrication substrate 500. The substrate alignment controller 207 may calculate the total amount of rotation correction for the final correction of the fabrication substrate 500 using the substrate rotation amount, the amount of rotation correction of the gripper units 205 and the residual, and inversely calculate the total amount of rotation correction to compare the total amount of rotation correction with the gap between the gripper units 205, thereby calculating an offset value for correcting the gap between the gripper units 205.

The substrate alignment controller 207 may add or subtract the offset value to or from the gap between the gripper units 205 to finally calculate a gripper gap setting value for adjusting the gap between the gripper units 205. The gripper gap setting value may be provided to the gripper driver 204 so that the gripper driver 204 may correct and adjust the gap between the gripper units 205.

The frame transfer member 202 may move the positions of the microscope mount module assembled and mounted on the main frame 201, the gripper driver 204 and the substrate alignment controller 207 together with the main frame 201 toward the fabrication substrate 500 (e.g., in the y-axis direction). To this end, the frame transfer member 202 may include at least one motor, a motor controller, a conveyor, etc.

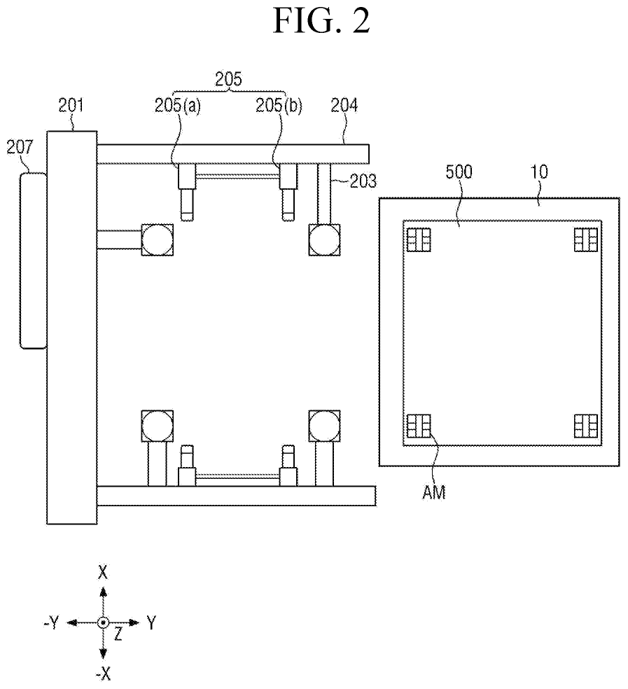

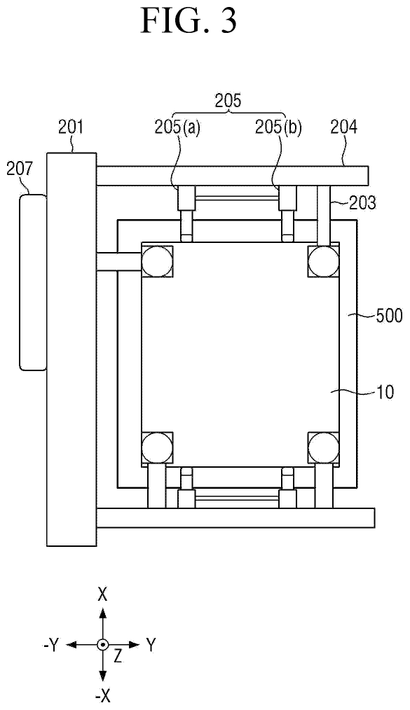

FIG. 2 is a top view showing the alignment device and the fabrication substrate on the loading plate shown in FIG. 1. FIG. 3 is a top view showing a process of checking if the fabrication substrate is properly aligned by the alignment device shown in FIG. 2.

Referring to FIGS. 2 and 3, in order to proceed with an alignment process, the frame transfer member 202 may move the optical microscopes 203, the gripper driver 204 and the substrate alignment controller 207 toward the fabrication substrate 500 on the loading plate 10 (e.g., in the y-axis direction) together with the main frame 201.

Accordingly, the optical microscopes 203 may be disposed at the positions in line with the alignment marks AM of the fabrication substrate 500 seated on the loading plate 10. For example, the optical microscopes 203 may be disposed at the positions in line with the alignment marks AM of the fabrication substrate 500 in the z-axis direction, which is the upward direction of the fabrication substrate 500.

The gripper driver 204 and the gripper units 205 may be moved in the y-axis direction by the frame transfer member 202, and accordingly the gripper driver 204 and the gripper units 205 may be disposed on at least one side (e.g., the sides in the x-axis and −x-axis directions) of the fabrication substrate 500. For example, the gripper units 205 may be moved to a side of the fabrication substrate 500 so that the gripper units may press the side of the fabrication substrate 500 in a direction (e.g., the side in the x-axis or −x-axis direction) to correct the position or angle of the fabrication substrate 500.

The gripper units 205 may be rotated with respect to the central axis between the gripper units 205 under the control of the gripper driver 204. To this end, the gripper units 205 may include first and second grippers 205(a) and 205(b) rotating around the central axis. The first and second grippers 205(a) and 205(b) may be rotated around the central axis between the first and second grippers 205(a) and 205(b) under the control of the gripper driver 204 to correct the position or angle of the fabrication substrate 500. For example, the first and second grippers 205(a) and 205(b) may further include a substrate holding portion formed to grip one side of the fabrication substrate 500 to rotate, push or pull it.

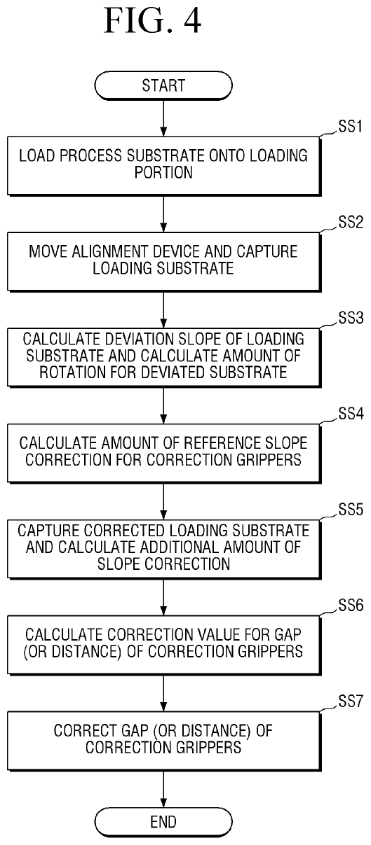

FIG. 4 is a flowchart illustrating a method of aligning a fabrication substrate and correcting the alignment state of the fabricating substrate by the alignment device according to the embodiment of the disclosure.

Referring to FIG. 4, a fabrication substrate 500 may be seated on a loading plate 10 by a separate loading device or a transfer robot. Multiple alignment marks AM for an alignment process of the fabrication substrate 500 may be formed in advance on the planar edges and the corners of the fabrication substrate 500. The fabrication substrate 500 with the alignment marks AM formed in advance may be seated on the loading plate 10 by a separate loading device or a transfer robot (step SS1).

Once the fabrication substrate 500 is seated on the loading plate 10, the frame transfer member 202 of the alignment device 200 may move the main frame 201 toward the fabrication substrate 500 (e.g., in the y-axis direction). The optical microscopes 203, the gripper driver 204 and the substrate alignment controller 207 may be moved toward the fabrication substrate 500 on the loading plate 10 (e.g., in the y-axis direction) by the frame transfer member 202 and the main frame 201. Accordingly, the optical microscopes 203 may be disposed at the positions in line with the alignment marks AM of the fabrication substrate 500 seated on the loading plate 10. For example, the optical microscopes 203 may be disposed at the positions in line with the alignment marks AM of the fabrication substrate 500 in the z-axis direction, which is the upward direction of the fabrication substrate 500.

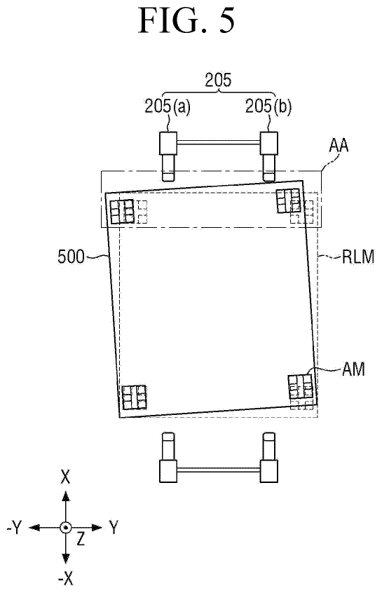

FIG. 5 is a top view showing a process of checking if the fabrication substrate is properly aligned by the substrate alignment device and a process of disposing grippers shown in FIG. 3.

Referring to FIG. 5 together with FIG. 3, the gripper driver 204 and the gripper units 205 along with the optical microscopes 203 may be moved in the y-axis direction by the frame transfer member 202, and accordingly the gripper driver 204 and the gripper units 205 may be disposed on at least one side (e.g., the sides in the x-axis and −x-axis directions) of the fabrication substrate 500.

Once the optical microscopes 203 are disposed on the fabrication substrate 500 on the loading plate 10 and the gripper driver 204 and the gripper units 205 are disposed on at least one side of the fabrication substrate 500, the substrate alignment controller 207 may start an alignment process of the fabrication substrate 500. For example, the substrate alignment controller 207 may transmit a capture control signal to each of the optical microscopes 203. The substrate alignment controller 207 may receive captured image data of the fabrication substrate 500 seated on the loading plate 10 from the optical microscopes 203 (step SS2).

The substrate alignment controller 207 may analyze the captured image data of the fabrication substrate 500 and extract multiple alignment marks AM included in the captured images. The substrate alignment controller 207 may detect the coordinates of the extracted alignment marks AM on an axis (e.g., the x-axis coordinates) and a deviation angle of the alignment marks AM relative to the reference line RLM.

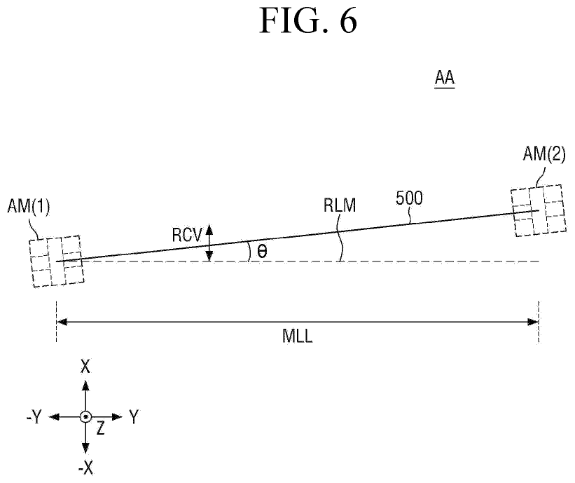

FIG. 6 is an enlarged view of area AA of FIG. 5 for illustrating a method of calculating the rotation amount of a fabrication substrate.

Referring to FIGS. 5 and 6, the substrate alignment controller 207 may extract the x-axis coordinates of the first and second alignment marks AM(1) and AM(2) arranged in the y-axis direction from the captured image of the fabrication substrate 500. The substrate alignment controller 207 may detect a first deviation angle of the first and second alignment marks AM(1) and AM(2) relative to a reference line RLM based on the difference between the x-axis coordinates of the first and second alignment marks AM(1) and AM(2).

$$Δ X = AM ( 1 ) . X - AM ( 2 ) . X \qquad [ Equation 1 ]$$

ΔX may be the first angle by which the first and second alignment marks AM(1) and AM(2) are deviated. AM(1).X may be the x-axis coordinate of the first alignment mark AM(1), and AM(2).X may be the x-axis coordinate of the second alignment mark AM(2). As in Equation 1, the substrate alignment controller 207 may detect a first deviation angle ΔX of the first and second alignment marks AM(1) and AM(2) relative to a reference line RLM based on the difference between the x-axis coordinates of the first and second alignment marks AM(1) and AM(2).

For example, the substrate alignment controller 207 may compare the x-axis coordinate of each of the first and second alignment marks AM(1) and AM(2) with the x-axis coordinate of the reference line RLM, to detect the first angle of the alignment marks AM relative to the reference line RLM.

The substrate alignment controller 207 may calculate the x-axis coordinates of the first and second alignment marks AM(1) and AM(2) and the first deviation angle of the alignment marks AM relative to the reference line RLM by using Equation 2, to calculate the substrate rotation amount θ for correcting the deviation angle of the fabrication substrate 500.

$$( θ ) = A TAN ( Δ X / MLL ) \times 180 / π \qquad [ Equation 2 ]$$

MLL may be the gap MLL between the first and second alignment marks AM(1) and AM(2).

The substrate alignment controller 207 may use Equations 1 and 2 to calculate the numerical information on the rotation angle and rotation amount, for example, the substrate rotation amount θ which may be used for correcting the deviation angle of the fabrication substrate 500 itself based on the gap MLL between the first and second alignment marks AM(1) and AM(2) (step SS3).

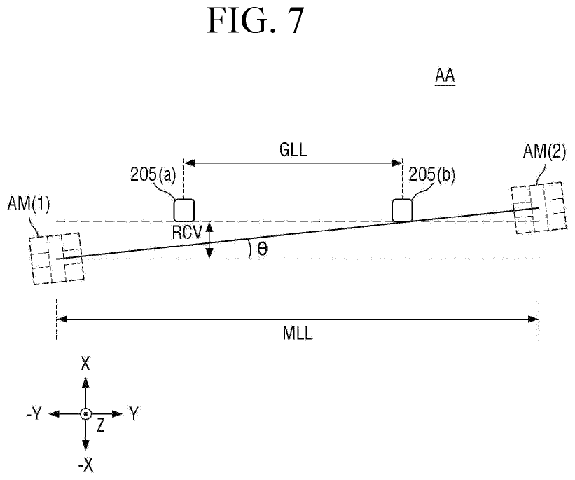

FIG. 7 is a view showing a method of calculating the rotation amount of grippers by converting the rotation amount of a fabrication substrate into the distance reference between alignment axes of the grippers.

Referring to FIG. 7, the substrate alignment controller 207 may calculate the rotation amount θ of the substrate based on the gap MLL between the first and second alignment marks AM(1) and AM(2) using Equation 3, and convert it into the amount of rotation correction RCV of the gripper units 205 based on the gap GLL between the first and second grippers 205(a) and 205(b).

$$RCV = TAN ( ( θ \times 180 / π ) \times GLL \qquad [ Equation 3 ]$$

The amount of rotation correction RCV may be a clockwise rotation amount of the first and second grippers 205(a) and 205(b) rotating in one axis direction (or clockwise) with respect to the central axis. The amount of rotation correction RCV may be the total rotation amount in the clockwise direction or the x-axis direction of the second gripper 205(b) among the first and second grippers 205(a) and 205(b) (step SS4).

The substrate alignment controller 207 may supply the amount of rotation correction RCV converted using Equation 3 to the gripper driver 204, so that the first and second grippers 205(a) and 205(b) are rotated based on the amount of rotation correction RCV. The first and second grippers 205(a) and 205(b) may be rotated clockwise or counterclockwise around the center axis between the first and second grippers 205(a) and 205(b) by the gripper driver 204, and the fabrication substrate 500 may also be rotated clockwise or counterclockwise.

The substrate alignment controller 207 may transmit a capture control signal to each of the optical microscopes 203 and receive the captured image data of the fabrication substrate 500 correctly rotated by the first and second grippers 205(a) and 205(b). The substrate alignment controller 207 may analyze the captured image data of the fabrication substrate 500 to detect again a second angle of the first and second alignment marks AM(1) and AM(2) correctly rotated relative to the reference line.

$$Δ {X}^{′} = A M ( 1 ) . X - A M ( 2 ) . X \qquad [ Equation 4 ]$$

ΔX′ may be the second angle by which the first and second alignment marks AM(1) and AM(2) are deviated after they have been corrected by being rotated. AM(1).X may be the x-axis coordinate of the first alignment mark AM(1) after it has been corrected by being rotated, and AM(2).X may be the x-axis coordinate of the second alignment mark AM(2) after it has been corrected by being rotated. As in Equation 4, the substrate alignment controller 207 may detect a se deviation angle ΔX′ of the first and second alignment marks AM(1) and AM(2) relative to a reference line RLM based on the difference between the x-axis coordinates of the first and second alignment marks AM(1) and AM(2) after they have been corrected by being rotated.

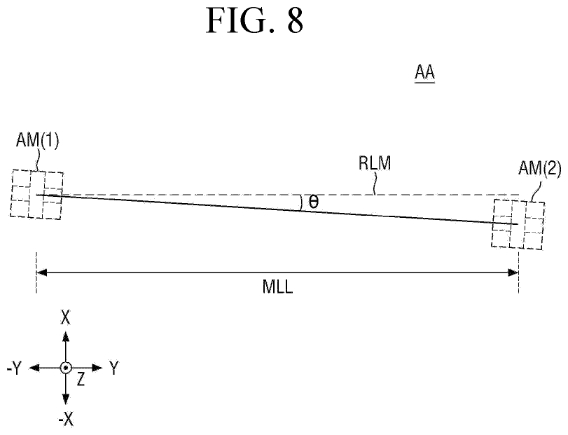

FIG. 8 is a view illustrating a method of measuring a residual of a fabrication substrate.

Referring to FIG. 8, the substrate alignment controller 207 may calculate the second deviation angle ΔX′ of the first and second alignment marks AM(1) and AM(2), the gap MLL between the first and second alignment marks AM(1) and AM(2), and the gap GLL between the first and second grippers 205(a) and 205(b) using Equation 5, to calculate an additional substrate rotation amount for additionally correcting the deviation angle of the fabrication substrate 500, i.e., a residual ΔCV (step S55).

$$Δ CV = Δ {X}^{′} \times GLL / MLL \qquad [ Equation 5 ]$$

As shown in Equation 6, the substrate alignment controller 207 may add or subtract the residual ΔCV to or from the amount of rotation correction RCV of the gripper units 205 based on the gap GLL between the first and second grippers 205(a) and 205(b), to calculate the total amount of rotation correction ΔCV′ for the final correction of the fabrication substrate 500.

$$Δ {CV}^{′} = RCV + Δ CV \qquad [ Equation 6 ]$$

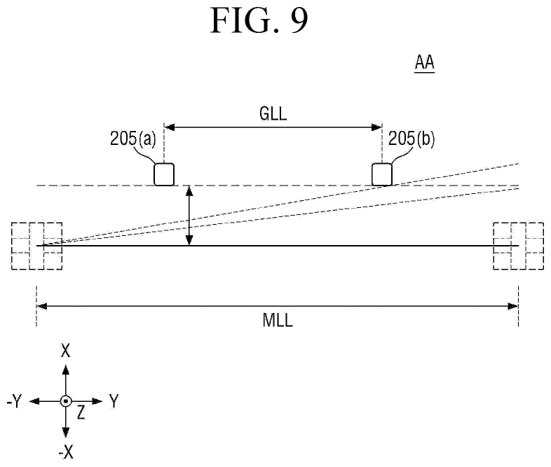

FIG. 9 is a view showing a method of adjusting and correcting the gap between alignment axes of grippers using measured residual.

As shown in Equation 7 below, the substrate alignment controller 207 may inversely calculate the total amount of rotation correction to compare it with the gap GLL between the first and second grippers 205(a) and 205(b), to calculate an offset value F_Offset for correcting the gap GLL between first and second grippers 205(a) and 205(b).

$$F\_Offset = Δ {CV}^{′} / ( TAN ( θ \times 180 / π ) - GLL \qquad [ Equation 7 ]$$

$$GGSet = GLL + F\_Offset \qquad [ Equation 8 ]$$

As shown in Equation 8, the substrate alignment controller 207 may add or subtract the offset value F_Offset to or from the gap GLL between the first and second grippers 205(a) and 205(b), to finally calculate a gripper gap setting value GGSet for adjusting the gap between the first and second grippers 205(a) and 205(b).

The substrate alignment controller 207 may provide the gripper gap setting value GGSet to the gripper driver 204 to correct and adjust the gap GLL between the first and second grippers 205(a) and 205(b) by the gripper driver 204 (step S77).

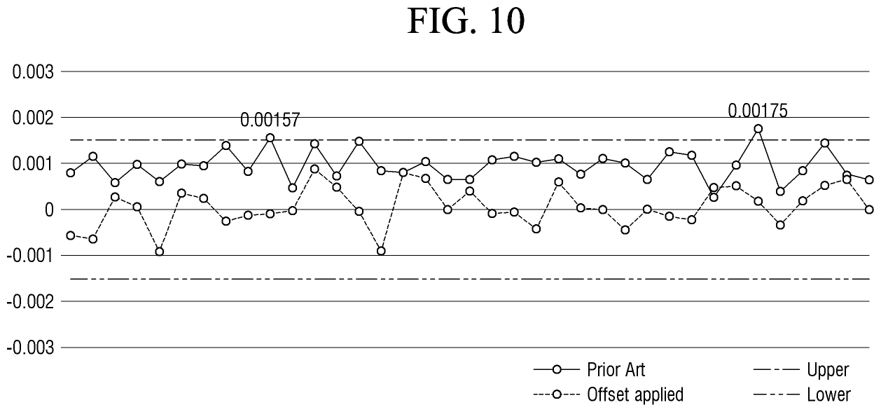

FIG. 10 is a graph showing results of comparing the amount of alignment correction of a fabrication substrate when the gap between alignment axes of grippers is adjusted, with the amount of alignment correction of a fabrication substrate according to the prior art.

It can be seen from FIG. 10 that the residual ΔCV is maintained around the value of approximately 0.001 in case that the deviation angle of the fabrication substrate 500 and the residual are continuously corrected without correcting the gap GLL between the first and second grippers 205(a) and 205(b).

In contrast, it can be seen that the residual ΔCV is maintained at approximately zero, which is minimized, in case that the gap GLL between the first and second grippers 205(a) and 205(b) is corrected by calculating the gripper gap setting value GGSet.

In this manner, according to the embodiment of the disclosure, it is possible to save the time and cost for fabricating a display panel by way of precisely adjusting the gap between alignment axes of the first and second grippers 205(a) and 205(b) for correcting the position or angle of the fabrication substrates 500 based on the residual ΔCV and correcting the alignment of the fabrication substrates 500 to reduce the number of alignment corrections, etc.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are the scope of the disclosure.

What is claimed is:

1. An apparatus for fabricating a display panel, the apparatus comprising:
a loading plate on which a fabrication substrate is loaded;
a plurality of optical microscopes that captures the fabrication substrate and a plurality of alignment marks of the fabrication substrate;
a gripper driver that aligns the fabrication substrate by adjusting a gap between gripper units and rotating the gripper units; and
a substrate alignment controller that calculates an amount of rotation correction for the gripper units based on a deviated angle of the fabrication substrate to supply the amount of rotation correction for the gripper units to the gripper driver, calculates a gripper gap setting value for adjusting the gap between the gripper units using a residual of the aligned fabrication substrate, and provides the gripper gap setting value to the gripper driver.

2. The apparatus of claim 1, wherein the gripper driver adjusts the gap between the gripper units disposed on a side in a direction of the fabrication substrate in real time based on the gripper gap setting value input from the substrate alignment controller, and aligns and corrects a deviation angle of the fabrication substrate by rotationally driving the gripper units around a central axis between the gripper units.

3. The apparatus of claim 1, wherein the substrate alignment controller receives captured image data of the fabrication substrate loaded on the loading plate from the plurality of optical microscopes, extracts the plurality of alignment marks included in the captured image data, detects coordinates of the plurality of alignment marks on an axis and the deviation angle of the plurality of alignment marks relative to a reference line, and calculates a substrate rotation amount for correcting the deviation angle of the fabrication substrate using the deviation angle of the plurality of alignment marks relative to the reference line.

4. The apparatus of claim 3, wherein the substrate alignment controller converts the substrate rotation amount calculated based on the gap between the plurality of alignment marks into an amount of rotation correction for the gripper units based on the gap between the gripper units, and supplies the amount of rotation correction to the gripper driver to rotate the gripper units according to the amount of rotation correction.

5. The apparatus of claim 4, wherein the substrate alignment controller additionally receives the captured image data of the optical microscopes on the loading plate from the optical microscopes, analyzes the captured image data to detect the coordinates of the plurality of alignment marks on the axis and the deviation angle of the plurality of alignment marks relative to the reference line, and calculates the residual of the fabrication substrate and the plurality of alignment marks using the coordinates of the plurality of alignment marks on the axis and the deviation angle of the plurality of alignment marks relative to the reference line.

6. The apparatus of claim 5, wherein the substrate alignment controller calculates a total amount of rotation correction for final correction of the fabrication substrate using the substrate rotation amount, the amount of rotation correction for the gripper units, and the residual, and calculates an offset value for correcting distance between the gripper units by inversely calculating the total amount of rotation correction to compare the total amount of rotation correction with the gap between the gripper units.

7. The apparatus of claim 6, wherein the substrate alignment controller calculates a gripper gap setting value for adjusting the gap between the gripper units by adding or subtracting the offset value to or from the gap between the gripper units, and provides the gripper gap setting value to the gripper driver to correct and adjust the gap between the gripper units in real time.

8. The apparatus of claim 3, wherein the substrate alignment controller extracts x-axis coordinates of a first alignment mark and a second alignment mark arranged in a y-axis direction among the plurality of alignment marks, and detects a first deviation angle of the first and second alignment marks relative to the reference line using a difference between the x-axis coordinates of the first and second alignment marks and Equation 1:
$$First Angle Δ X = AM ( 1 ) . X - AM ( 2 ) . X , \qquad [ Equation 1 ]$$
wherein ΔX is the first deviation angle of the first and second alignment marks,
AM(1).X is the x-axis coordinate of the first alignment mark, and
AM(2).X is the x-axis coordinate of the second alignment mark.

9. The apparatus of claim 8, wherein the substrate alignment controller calculates the x-axis coordinates of the first and second alignment marks and the first deviation angle of the plurality of alignment marks relative to the reference line using Equation 2 to calculate a substrate rotation amount for correcting the deviation angle of the fabrication substrate, and calculates the substrate rotation amount calculated based on a gap between the first and second alignment marks using Equation 3, and converts the substrate rotation amount into an amount of rotation correction for a first gripper unit and a second gripper unit based on the gap between the first and second gripper units among the gripper units:
$$Substrate Rotation Amount ( θ ) = A TAN ( Δ X / MLL ) \times 180 / π \qquad [ Equation 2 ]$$
$$Amount of Rotation Correction RCV = TAN ( ( θ \times 180 / π ) \times GLL \qquad [ Equation 3 ]$$
wherein Amount (θ) is the substrate rotation amount,
MLL is the gap between the first and second alignment marks,
RCV is the amount of rotation correction, and
GLL is the gap between the first and second grippers.

10. The apparatus of claim 9, wherein the substrate alignment controller provides the amount of rotation correction to the gripper driver so that the first and second grippers are rotated based on the amount of rotation correction, and further receives the captured image data of the fabrication substrate after the fabrication substrate has been corrected by being rotated by the first and second grippers, and detects a second deviation angle of the first and second alignment marks using Equation 4:
$$Second Angle Δ {X}^{′} = A M ( 1 ) . X - A M ( 2 ) . X , \qquad [ Equation 4 ]$$
wherein ΔX′ is the second deviation angle of the first and second alignment marks.

11. The apparatus of claim 10, wherein the substrate alignment controller calculates the second deviation angle of the first and second alignment marks, the gap between the first and second alignment marks, and the gap between the first and second grippers using Equation 5 to calculate the residual for additionally correcting the deviation angle of the fabrication substrate, and adds or subtracts the residual to or from the amount of rotation correction for the first and second grippers based on the gap between the first and second grippers using Equation 6 to calculate a total amount of rotation correction for final correction of the fabrication substrate:
$$Residual Δ CV = Δ {X}^{′} \times GLL / MLL \qquad [ Equation 5 ]$$
$$Total Amount of Rotation Correction Δ {CV}^{′} = R CV + CV , \qquad [ Equation 6 ]$$
wherein ΔCV′ is the total amount of rotation correction.

12. The apparatus of claim 11, wherein the substrate alignment controller inversely calculates the total amount of rotation correction using Equation 7 to compare the total amount of rotation correction with the gap between the first and second grippers, to calculate an offset value for correcting the gap between first and second grippers, and adds or subtracts the offset value to or from the gap between the first and second grippers using Equation 8 to calculate a gripper gap setting value for adjusting the gap between the first and second grippers:
$$Offset Value F\_Offset = Δ {CV}^{′} / ( TAN ( θ \times 180 / π ) - GLL ) \qquad [ Equation 7 ]$$
$$Gripper Gap Setting Value GGSet = GLL + F\_Offset , \qquad [ Equation 8 ]$$
wherein F_Offset is the offset value for correcting the gap between first and second grippers, and
GGSet is the gripper gap setting value.

13. The apparatus of claim 1, further comprising:
a microscope mount module that mounts the plurality of optical microscopes and fixed and assembled to a main frame; and
a frame transfer member that moves the main frame, the microscope mount module, the gripper driver and the substrate alignment controller toward the fabrication substrate along rails.

14. A method for fabricating a display panel, the method comprising:
loading a fabrication substrate onto a loading plate;
capturing the fabrication substrate and alignment marks of the fabrication substrate with a plurality of optical microscopes;
aligning the fabrication substrate by adjusting a gap between gripper units by a gripper driver and rotating the gripper units; and
calculating an amount of rotation correction for the gripper units based on a deviation angle of the fabrication substrate to supply the deviation angle of the fabrication substrate to the gripper driver,
calculating a gripper gap setting value for adjusting the gap between the gripper units using a residual of the aligned fabrication substrate, and
providing the gripper gap setting value to the gripper driver.

15. The method of claim 14, wherein the aligning of the fabrication substrate by rotating the gripper units comprises:
adjusting the gap between the gripper units disposed on a side in a direction of the fabrication substrate in real time based on the gripper gap setting value input from a substrate alignment controller; and
aligning and correcting the deviation angle of the fabrication substrate by rotationally driving the gripper units around a central axis between the gripper units.
